(19) United States
(12) Patent Application Publication
(10) Pub. No.: US 2017/0343604 A1
(43) Pub. Date: Nov. 30, 2017

(54) TEST DEVICE

(71) Applicants: Fu Tai Hua Industry (Shenzhen) Co., Ltd., Shenzhen (CN); HON HAI PRECISION INDUSTRY CO., LTD., New Taipei (TW)

(72) Inventors: KANG-XIAN YANG, Shenzhen (CN); WEN-HSIEN HUANG, New Taipei (TW); I-CHENG HUANG, New Taipei (TW); KUN-JIA HSIEH, New Taipei (TW)

(21) Appl. No.: 15/477,081

(22) Filed: Apr. 1, 2017

(30) Foreign Application Priority Data
May 28, 2016 (CN) 201610364728.1

(51) Int. Cl. G01R 31/317; G01R 1/073; G01R 31/28; H01L 21/66

(52) U.S. Cl. CPC G01R 31/31717; H01L 22/14; G01R 31/31702; G01R 1/07328; G01R 31/2889; G01R 31/2853; G01R 31/2891

(57) ABSTRACT

A test device for testing an electronic device has a base, a first mounting plane, a first support element, a plurality of second support elements, a plurality of test elements, and a control unit. The first mounting plane is mounted on the base. The first support element is slidable on the first mounting plane, the second support elements are slidable on the first support element, and the test elements are slidable on the second support elements. The control unit electrically coupled to the test elements controls the test elements to provide impact force on the electronic device.

### CROSS-REFERENCE TO RELATED APPLICATIONS

This application claims priority to Chinese Patent Application No. 201610364728.1 filed on May 28, 2016, the contents of which are incorporated by reference herein.

### FIELD

The subject matter herein generally relates to a test device for testing an electronic device.

### BACKGROUND

Most commercial electronic devices, such as smart phone, tablet, and personal computer, include a display to show information, image, and video. However, quality of the display may be reduced if the manufacturing process is unstable. Thus, the display of the electronic device may be easily damaged due to external impact.

### BRIEF DESCRIPTION OF THE DRAWINGS

Implementations of the present disclosure will now be described, by way of example only, with reference to the attached figures.

FIG. 1 is a schematic illustration of one exemplary embodiment of a test device.

FIG. 2 is an exploded view of one exemplary embodiment of the test device of FIG. 1.

FIG. 3 is a block diagram of one exemplary embodiment of the test device coupled to an electronic device.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the exemplary embodiments described herein. However, it will be understood by those of ordinary skill in the art that the exemplary embodiments described herein can be practiced without these specific details. In other instances, methods, procedures, and components have not been described in detail so as not to obscure the related relevant feature being described. The drawings are not necessarily to scale and the proportions of certain parts can be exaggerated to better illustrate details and features. The description is not to be considered as limiting the scope of the exemplary embodiments described herein.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “comprising” means “including, but not necessarily limited to”; it specifically indicates open-ended inclusion or membership in a so-described combination, group, series, and the like.

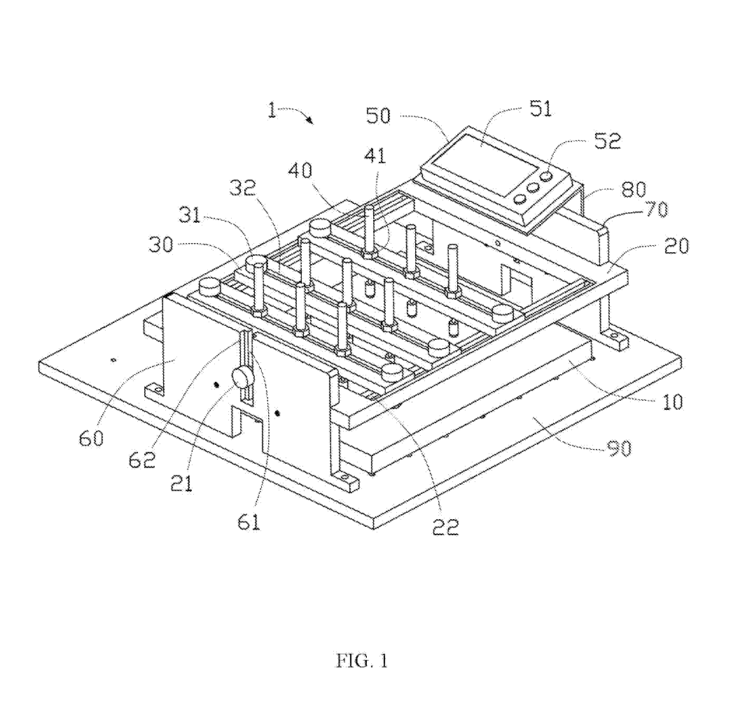

FIG. 1 illustrates an exemplary embodiment of a test device 1. In at least one exemplary embodiment, the test device 1 can include a bearing element 10, a first support element 20, a plurality of second support elements 30, a plurality of test elements 40, a control unit 50, a first mounting plane 60, a second mounting plane 70, a third mounting plane 80, and a base 90. FIG. 1 illustrates only one example of the test device 1, the test device 1 in other exemplary embodiments can include more or fewer components than as illustrated, or have a different configuration of the various components.

In at least one exemplary embodiment, the bearing element 10 for supporting a device (not shown) to be tested is installed on the base 90. The first mounting plane 60 and the second mounting plane 70 are mounted on the base 90. The bearing element 10 is installed between the first mounting plane 60 and the second mounting plane 70. The first support element 20 is also installed between the first mounting plane 60 and the second mounting plane 70. The plurality of second support elements 30 are installed on the first support element 20. Each of the test elements 40 is installed on one of the second support elements 30 and aimed at the device placed on the bearing element 10. For example, each of the test elements 40 can be perpendicular to the bearing element 10 for facing toward the device to be tested. The control unit 50 can control the test elements 40 to move up and down to provide impact force on the device when the device is placed on the bearing element 10 for testing. In at least one exemplary embodiment, the first support element 20 is perpendicular to the first mounting plane 60 and the second mounting plane 70, each of the second support elements 30 is perpendicular to the first support element 20, and each of the test elements 40 is perpendicular to one of the second support elements 30.

In at least one exemplary embodiment, the control unit 50 can be a programmable logic controller (PLC). The control unit 50 can be installed on the third mounting plane 80 mounted on the base 90. The control unit 50 can include a display unit 51 and a plurality of button 52. The display unit 51 can show test results, and the buttons 52 can control the control unit 50 by user inputs. For example, user can turn on or turn off the control unit 50, or start the test by pressing one of the buttons 52. In at least one exemplary embodiment, the control unit 50 is mounted on the third mounting plane 80. The third mounting plane 80 is mounted on the base 90.

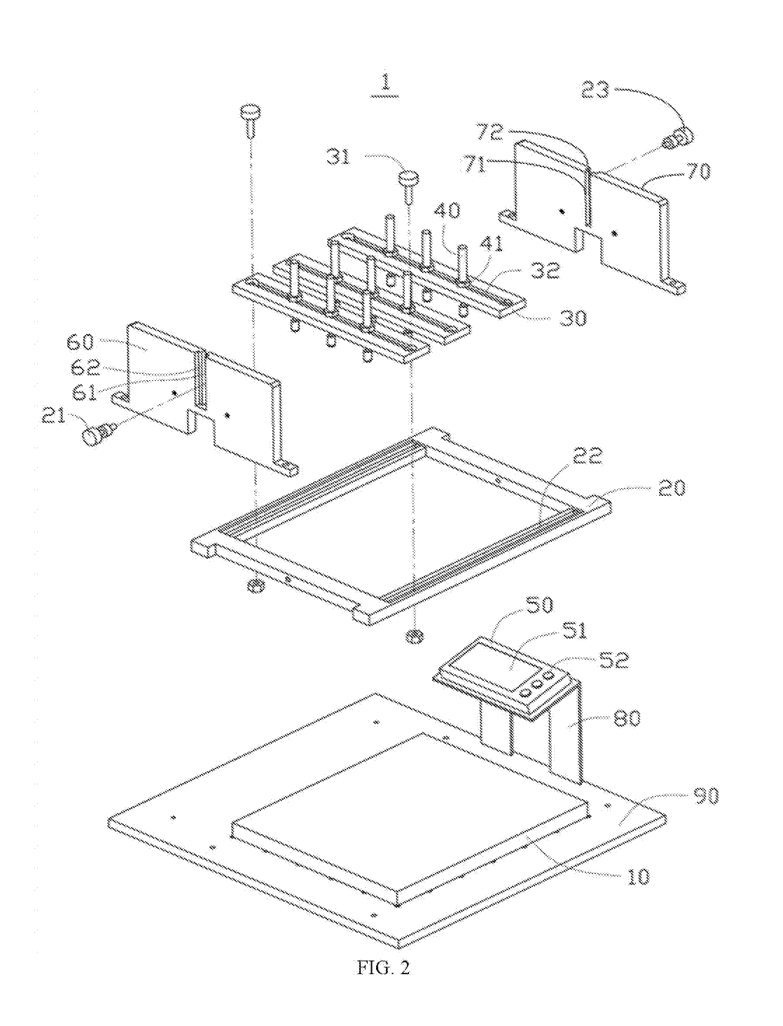

FIG. 2 is an exploded view of one exemplary embodiment of the fastening device of FIG. 1. The first mounting plane 60 includes a first slit 61 and a first sliding rail 62 formed on the first slit 61, and the second mounting plane 70 includes a second slit 71 and a second sliding rail 72 formed on the second slit 71. The first support element 20 includes two first mounting elements 21 and 23 formed on two opposite sides of the first support element 20. The first mounting element 21 passes through the first slit 61 of the first mounting plane 60 and abuts the first sliding rail 62 of the first mounting plane 60, so that the first mounting element 21 is slidable along the first sliding rail 62. Thus, the first support element 20 is installed on the first mounting plane 60 by passing the first mounting element 21 through the first sliding rail 62 and is slidable on the first mounting plane 60 by sliding the first mounting element 21 along the first sliding rail 62. The first mounting element 23 passes through the second slit 71 of the second mounting plane 70 and abuts the second sliding rail 72 of the second mounting plane 70, so that the first mounting element 23 is slidable along the second sliding rail 72. Thus, the first support element 20 is installed on the second mounting plane 70 by passing the first mounting element 23 through the second sliding rail 72 and is slidable on the second mounting plane 70 by sliding the first mounting element 23 along the second sliding rail 72.

In at least one exemplary embodiment, each of the first mounting elements 21 and 23 can be a first fastening element, such as a pair of screw and nut, or a clamp. When the first fastening element is loosened, the first mounting elements 21 and 23 can respectively slide along the first sliding rail 62 and the second sliding rail 72 to adjust the attitude of the first support element 22 with respect to the first mounting plane 60 and the second mounting plane 70. When the first fastening element is tightened, the first support element 22 is mounted on the first mounting plane 60 and the second mounting plane 70.

In at least one exemplary embodiment, each end of the second support elements 30 includes a second mounting element 31. The first support element 20 includes two first sliding slots 22 formed on two opposite sides of the first support element 20. Each of the second mounting elements 31 passes through a specific one of the first sliding slots 22 and abuts the specific first sliding slot 22, so that each of the second mounting elements 31 is slidable along the specific first sliding slot 22. Thus, the second support elements 30 are installed on the first support element 20 by the second mounting elements 31 and are slidable on the first support element 20 through the second mounting elements 31. In at least one exemplary embodiment, each of the second mounting elements 31 can be a second fastening element, such as a pair of screw and nut, or a clamp. When the second fastening element is loosened, the second mounting element 31 can slide along the specific first sliding slot 22 to adjust the position of the second support element 30 with respect to the first specific sliding slot 22. When the second fastening element is tightened, the second support element 30 is mounted on the first support element 20.

In at least one exemplary embodiment, each of the second support elements 30 includes a second sliding slot 32. Each of the test elements 40 includes a third mounting element 41. Each of the test elements 40 passes through a specific one of the second sliding slots 32 and a specific one of the third mounting elements 41 abutting the specific second sliding slot 32. Each of the mounting elements 41 is slidable along the specific second sliding slot 32, and each of the test elements 40 is slidable on the second support elements 30. In at least one exemplary embodiment, the third mounting element 41 can be a third fastening element, such as a nut, and a clamp. When the third fastening element is loosened, the third mounting element 41 can slide along the specific second sliding slot 32 to adjust the position of the test element 40 with respect to the specific second sliding slot 32. When the third fastening element is tightened, the test element 40 is installed on the second support element 30.

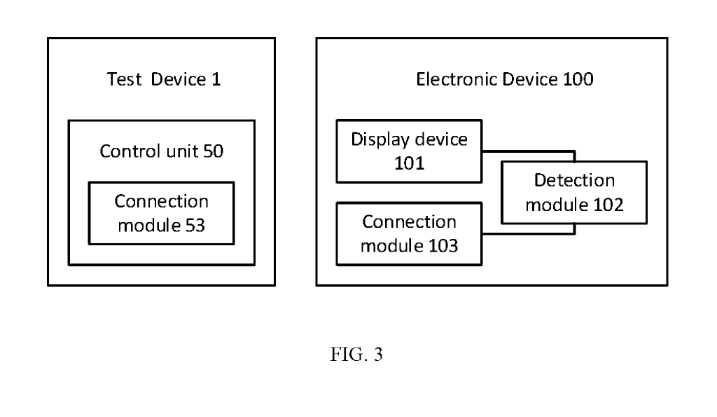

FIG. 3 illustrates an exemplary embodiment of the test device 1 coupled to an electronic device 100. In at least one exemplary embodiment, the test device 1 is used to test an electronic device 100. In at least one exemplary embodiment, the electronic device 100 can be a mobile phone, a tablet, a notebook, or other electronic device. In at least one exemplary embodiment, the control unit 50 of the test device 1 include a connection module 53, and the electronic device 100 includes a display device 101, a detection module 102, and a connection module 103. In at least one exemplary embodiment, the test device 1 is used to test the display device 101 of the electronic device 100. Before the test device 1 executes a test process on the display device 101 of the electronic device 100, the attitude of the first support element 20 can be adjusted based on a size dimension of the electronic device 100 by the first mounting element 21 and 23. In at least one exemplary embodiment, the attitude of the first support element 20 can be adjusted based on the thickness of the electronic device 100. In addition, the positions of the second support elements can be adjusted based on another size dimension of the display device 101 by the second mounting elements 31, and the positions of the test elements can be adjusted to determine a plurality of impact points on the display device 101 by the third mounting element 41. In at least one exemplary embodiment, the positions of the second support elements can be adjusted based on the length and the width of the display device 101.

In at least one exemplary embodiment, the control unit 50 is electrically coupled to the test elements 40 to control the test elements 40 to provide impact force on the display device 101. A plurality of impact parameters including impact frequency, impact power, and impact duration of the test elements 40 can be set by the control unit 50. The control unit 50 can control the test elements 40 to provide the impact force on the display device 101 according to the plurality of impact parameters and check the quality of the display device 101 by testing the impact resistance of the display device 101.

In at least one exemplary embodiment, the detection module 102 can detect the display device 101 to generate a detection result including number of damaged points and damage degree after the test process completes. The connection module 103 of the electronic device 100 receives the detection result from the detection module 102 and transmits the detection result to the connection module 53 of the control unit 50 in the test device 1. The control unit 50 can receive the detection result from the connection module 102 of the electronic device 100 and show the detection result on the display unit 51.

The exemplary embodiments shown and described above are only examples. Even though numerous characteristics and advantages of the present disclosure have been set forth in the foregoing description, together with details of the structure and function of the present disclosure, the disclosure is illustrative only, and changes can be made in the detail, including in matters of shape, size, and arrangement of the parts within the principles of the present disclosure, up to and including the full extent established by the broad general meaning of the terms used in the claims.

What is claimed is:

1. A test device for testing an electronic device, comprising:
a base;
a first mounting plane mounted on the base;
a first support element slidable on the first mounting plane;
a plurality of second support elements slidable on the first support element;
a plurality of test elements slidable on the second support elements; and
a control unit electrically coupled to the test elements and the control unit configured to control the test elements to provide impact force on the electronic device.

2. The test device of claim 1, wherein the first support element is perpendicular to the first mounting plane, each of the second support elements is perpendicular to the first support element, and each of the test elements is perpendicular to one of the second support elements.

3. The test device of claim 1, comprising:
a second mounting plane mounted on the base, wherein the first support element is slidable on the second mounting plane and is installed between the first mounting plane and the second mounting plane;
a bearing element installed on the base for supporting the electronic device, wherein the bearing element is installed between the first mounting plane and the second mounting plane; and
a third mounting plane mounted on the base, wherein the control unit is installed on the third mounting plane.

4. The test device of claim 1, wherein the first mounting plane includes a slit and a sliding rail formed on the slit, and the first support element includes a first mounting element installed in the slit and is slidable along the sliding rail of the first mounting plane.

5. The test device of claim 4, wherein the first mounting element includes a first fastening element to mount the first support element on the first mounting plane.

6. The test device of claim 1, wherein the first support element includes a first sliding slot, and each of the second support elements includes a second mounting element installed in and is slidable along the first sliding slot.

7. The test device of claim 6, wherein each of the second mounting elements includes a second fastening element to mount a specific one of the second support elements on the first support element.

8. The test device of claim 1, wherein each of the second support elements includes a second sliding slot, and each of the test elements includes a third mounting element installed in and is slidable along a specific one of the second sliding slots.

9. The test device of claim 8, wherein each of the third mounting elements includes a third fastening element to mount a specific one of the test elements on a specific one of the second support elements.

10. A test device for testing an electronic device, comprising:
a first support element;
a plurality of second support elements installed on the first support element;
a plurality of test elements slidable on the second support elements; and
a control unit electrically coupled to the test elements and the control unit configured to control the test elements to test the electronic device.

11. The test device of claim 10, comprising:
a base; and
a first mounting plane mounted on the base, wherein the first support element is installed on the first mounting plane.

12. The test device of claim 11, comprising:
a second mounting plane mounted on the base, wherein the first support element is installed between the first mounting plane and the second mounting plane; and
a bearing element installed between the first mounting plane and the second mounting plane on the base for supporting the electronic device when the electronic device is tested; and
a third mounting plane mounted on the base, wherein the control unit is installed on the third mounting plane.

13. The test device of claim 11, wherein each of the test elements is perpendicular to the bearing element, and the control unit controls the test elements to provide impact force on the electronic device.

14. The test device of claim 10, wherein the first mounting plane includes a slit and a sliding rail formed on the slit, and the first support element includes a first mounting element installed in the slit and is slidable along the sliding rail.

15. The test device of claim 14, wherein the first mounting element includes a first fastening element to mount the first support element on the first mounting plane.
